(19) United States
(12) Patent Application Publication
(10) Pub. No.: US 2008/0079143 A1
(43) Pub. Date: Apr. 3, 2008

(54) SCALABLE INTERCHANGEABLE MULTIBAND POWER PACKAGE MOUNTING APPARATUS

(75) Inventors: Edmund B. Boucher, Davie, FL (US); George C. Anderson, Sunrise, FL (US); Jose N. Diaz, Pembroke Pines, FL (US)

Correspondence Address: MOTOROLA, INC, 1303 EAST ALGONQUIN ROAD, IL01/3RD, SCHAUMBURG, IL, 60196, US

(73) Assignee: MOTOROLA, INC., Plantation, FL (US)

(21) Appl. No.: 11/536,570

(22) Filed: Sep. 28, 2006

(51) Int. Cl. H01L 23/34

(52) U.S. Cl. 257/706

(57) ABSTRACT

A miniature multiple die packaging assembly suitable for use in a radio is provided. The assembly includes a heatsink having contact with a chassis of the radio, a circuit board containing a plurality of active devices having leads to a perimeter of the circuit board, and a mating board having an opening. The mating board attaches along a top perimeter of the circuit board to pass the leads of the circuit board for extending a connection of the active devices to a radio board. The plurality of active devices are in contact and coplanar with the heatsink for providing efficient heat dissipation. The circuit board can interchangeably accept single package die or multiple package die having different sizes and layouts.

### FIELD OF THE INVENTION

The present invention relates to mobile devices, and more particularly, to component design.

### BACKGROUND

The use of portable electronic devices, radios, and mobile communication devices has increased dramatically in recent years. Moreover, the demand for mobile devices that communicate with other devices or systems is increasing. This includes communication features which allow for multi-band operation. A multi-band radio can transmit among various communications frequencies. One of the challenges in a transmitter section of a multiband or software defined radio is to design a power amplifier that can operate across a wide frequency spectrum, for example, from 100 MHz to 900 MHz. As shown in FIG. 1, one solution to this problem is to include complete amplifier lineups for each frequency band and switch the power amplifiers in or out accordingly. For example, as shown in FIG. 1, three power amplifiers are shown each providing operation for a different frequency band. In practice, a manufacturer can include power amplifiers for specific frequency bands requested. As shown in FIG. 2, the three power amplifiers requested can then be integrated together to provide tri-band operation.

Customers, however, may not want to pay for the ability to access multiple bands and may only desire a dual or single band radio. Similarly, the Manufacturer may not want to populate every radio board with costly power transistors if the customers are not willing to pay for the additional multi-band functionality. The problem can also escalate in complexity as other customers may request several different combinations of radio bands. Each radio band may require a different size power amplifier die with different lead connections. Therefore, what is needed is a packaging assembly that allows the manufacturer to include any combination of power die in a manner that is flexible, cost efficient, and uses a minimum of space on the radio board.

### SUMMARY

Embodiments of the invention are directed to a miniature die mounting apparatus suitable for use in a radio. The apparatus can include a heatsink, a circuit board, and a mating board. The circuit board contains a plurality of active devices having leads to a perimeter of the circuit board. The circuit board is communicatively coupled to a radio board. The active devices are high power amplifiers for transmitting communication signals. The mating board provides an opening that protects wire bonds of the plurality of active devices. The mating board attaches along the perimeter of the circuit board to pass the leads of the circuit board for extending a connection of the active devices. The leads of the circuit board extend to pads of the mating board at pre-configured locations for providing interchangeability in accommodating active devices of differing sizes and pin layouts. The radio board has pads at compatible locations with the pre-configured locations that accept either individual Integrated Circuit (IC) packages or multiple IC packages for power amplifier dies equally.

The plurality of active devices are in coplanar contact with the heatsink to provide efficient heat dissipation. The heatsink provides a planar surface for efficiently dissipating heat from the plurality of active devices when the heatsink is in direct contact with a chassis of the radio. Heat is efficiently dissipated from the top of the miniature die mounting apparatus away from the radio board. In one arrangement, the active devices are arranged on the circuit board and aligned with a signal flow from gate to drain to minimize a size of the apparatus. For example, a longest dimension of an active device is arranged parallel to the signal flow. The miniature die mounting apparatus is a leadless, surface mount package design to efficiently dissipate heat.

### BRIEF DESCRIPTION OF THE DRAWINGS

The features of the system, which are believed to be novel, are set forth with particularity in the appended claims. The embodiments herein, can be understood by reference to the following description, taken in conjunction with the accompanying drawings, in the several figures of which like reference numerals identify like elements, and in which:

FIG. 1 is a schematic of a power amplifier package design of the prior art in accordance with the embodiments of the invention;

FIG. 2 is a schematic of a combined power amplifier package design of the prior art in accordance with the embodiments of the invention;

FIG. 3 is a schematic of a single power amplifier package of the prior art in accordance with the embodiments of the invention;

FIG. 4 is a schematic of a scalable device in accordance with the embodiments of the invention;

FIG. 5 is a schematic of a scalable device showing multiple active devices in accordance with the embodiments of the invention;

FIG. 6 is a perspective view of the scalable device of FIG. 5 in accordance with the embodiments of the invention;

FIG. 7 is another perspective view of the scalable device of FIG. 5 in accordance with the embodiments of the invention;

FIG. 8 is a schematic for the components of the scalable device of FIG. 5 in accordance with the embodiments of the invention;

FIG. 9 is a schematic of a scalable device having only one active device in accordance with the embodiments of the invention;

FIG. 10 is a diagram for a multiple die package in accordance with the embodiments of the invention;

FIG. 11 is an exemplary application for a scalable device using a multiple device package in accordance with the embodiments of the invention; and

FIG. 12 is an exemplary application for a scalable device using single die packages in accordance with the embodiments of the invention.

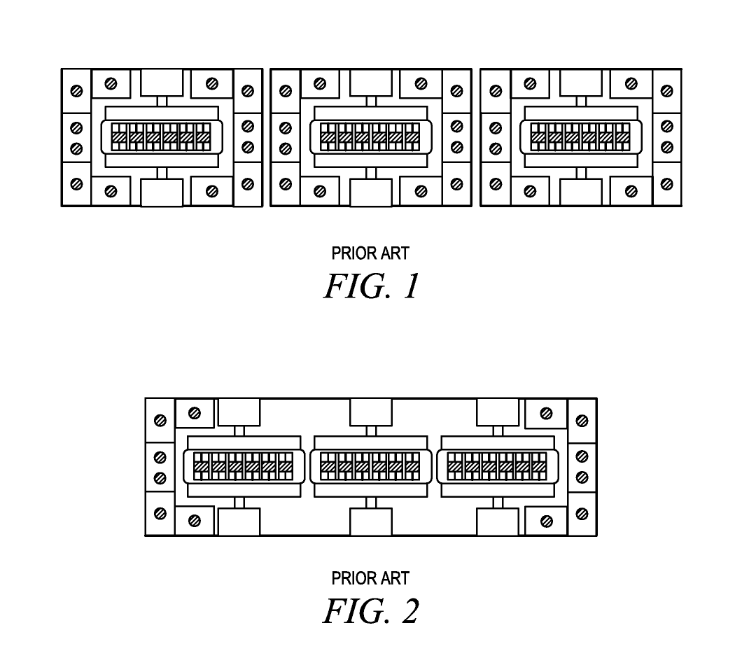

### DETAILED DESCRIPTION

While the specification concludes with claims defining the features of the embodiments of the invention that are regarded as novel, it is believed that the method, system, and other embodiments will be better understood from a consideration of the following description in conjunction with the drawing figures, in which like reference numerals are carried forward.

As required, detailed embodiments of the present method and system are disclosed herein. However, it is to be understood that the disclosed embodiments are merely exemplary, which can be embodied in various forms. Therefore, specific structural and functional details disclosed herein are not to be interpreted as limiting, but merely as a basis for the claims and as a representative basis for teaching one skilled in the art to variously employ the embodiments of the present invention in virtually any appropriately detailed structure. Further, the terms and phrases used herein are not intended to be limiting but rather to provide an understandable description of the embodiment herein.

The terms “a” or “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The term “coupled,” as used herein, is defined as connected, although not necessarily directly, and not necessarily mechanically.

The term “coplanar” can be defined as within a same plane and having a same height. The term “die” can be defined as a imprinted circuit design. The term “leads” can be defined as pins from an electrical device. The term “pads” can be defined as a electrical connection point for a lead. The term “wire bond” can be defined as a wired connection of a lead to a circuit board. The term “chassis” can be defined as a housing of a radio. The term “dimension” can be defined as the length, width, or height of a component. The term “heatsink” can be defined as a component or material that dissipates heat. The term “perimeter” can be defined as an outer portion.

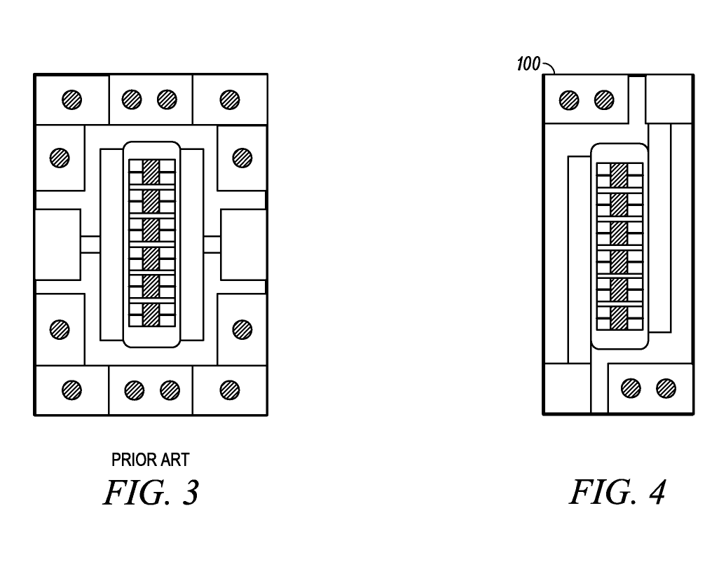

Broadly stated, embodiments of the invention are directed to a scalable interchangeable multiband power package mounting device. The device is scalable and interchangeable since it allows a manufacturer to place any number of individually packaged die or a single package with multiple die on a radio board or any combination thereof. Each die can provide a power amplifier for a specific frequency band thereby providing a multiband power package. The device can be mounted in a radio to provide powered transmission on a Radio Frequency communication deck. The interchangeable multiband power package mounting device can support a multiplicity of dissimilar dies in one package to reduce an overall cost and size of the package. As an example, a single package die of the prior art is shown in FIG. 3. For comparison, a single package die of the scalable interchangeable multiband power package mounting device 100 (herein termed scalable device) of one embodiment of the invention is shown in FIG. 4. Notably, the size of the scalable device 100 is sufficiently less than the size of the prior art of FIG. 3 due to the configuration of the scalable device. As customers demand different frequency band combinations and performance, individual dies can be added and/or interchanged to allow flexibility in design. That is, the multiple scalable device can be grouped together and/or interchanged to provide support for different frequency bands.

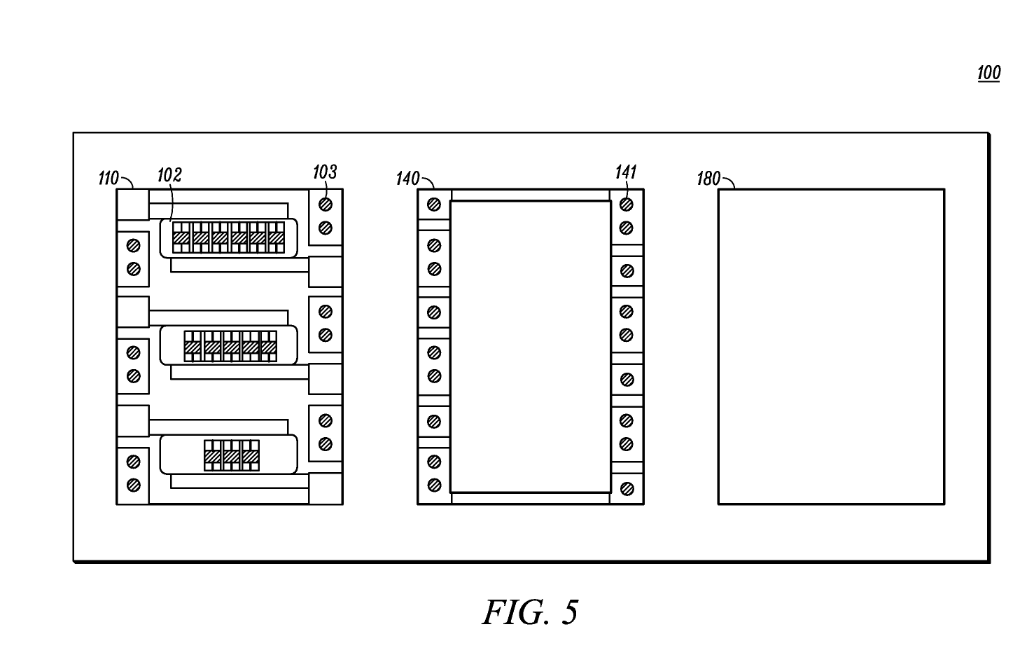

Referring to FIG. 5, the scalable device 100 is shown in greater detail. The scalable device 100 includes a circuit board 1 10, a mating board 140 having an opening, and a heatsink 180. The circuit board 110 contains a plurality of active devices 102 having leads 103 extending to a perimeter of the circuit board 110. The leads 103 of the circuit board extend to pads 141 of the mating board 141 at pre-configured locations for providing interchangeability in accommodating active devices of differing sizes. In practice, the mating board 140 can be mounted to a radio board (not shown) of a radio having pads at compatible locations with the pre-configured locations that accept either individual Integrated Circuit (IC) packages or multiple IC packages equally. The heatsink 180 provides a planar surface for efficiently dissipating heat from the plurality of active devices when the heatsink is in direct contact with at least a portion of a chassis of the radio.

The active devices 102 can be power amplifiers supporting a specific frequency band of operation. The circuit board can accept single package die or multiple package dies. For example, a first active device 102 can provide VHF communication within a first frequency band, a second active device 102 can provide UHF communication within a second frequency band, and a third active device 102 can provide low-band radio communication within a third frequency band. The active devices 102 can also be connected to the heatsink 180 for dissipating heat during power amplifier operation. The mating board 140 fits around the active devices 102 of the circuit board 110 and passes the leads 103 of the active devices 102 to extend a connection of the active devices. Notably, leads of the active devices 102 can be directly soldered to the heat sink for heat dissipation.

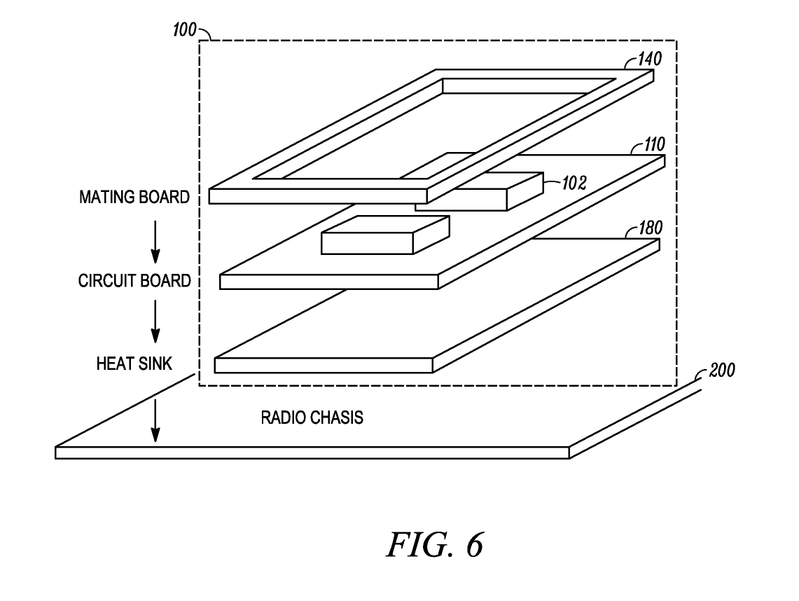

Referring to FIG. 6, a perspective view of the scalable device 100 coupled to a radio chassis 200 is shown. In particular, the perspective view illustrates how the mating board 140, the circuit board 110, and the heat sink 180 are assembled together. Moreover, the perspective view shows how the scalable device 100 mates to the radio chassis 200 to provide heat dissipation. Notably, the heatsink 180 has a planar surface for efficiently dissipating heat from the plurality of active devices 102 when the heatsink 180 is in direct contact with at least a portion of a chassis 200 of the radio. That is, the planar surface of the heatsink 180 rests against a surface of the chassis 200 to conduct heat away from the active devices 102 on the circuit board. In practice, at least one lead (not shown), such as a ground lead, of an active device 102 of the circuit board 110 can be directly soldered to the heatsink 180. Accordingly, all the active devices are coplanar with the heatsink 180 since the leads are directly soldered to the board. This provides efficient heat dissipation since the heat sink is planar with the chassis 200. Moreover, the heat is dissipated in a direction away from the mating board 140 which is generally connected to a radio board (not currently shown). The mating board brings the leads of the active devices to pre-configured locations along the perimeter. That is, the mating board 140, which extends the leads of the active devices to pads on the mating board 140, is typically electrically coupled to a radio board for providing radio communication operation.

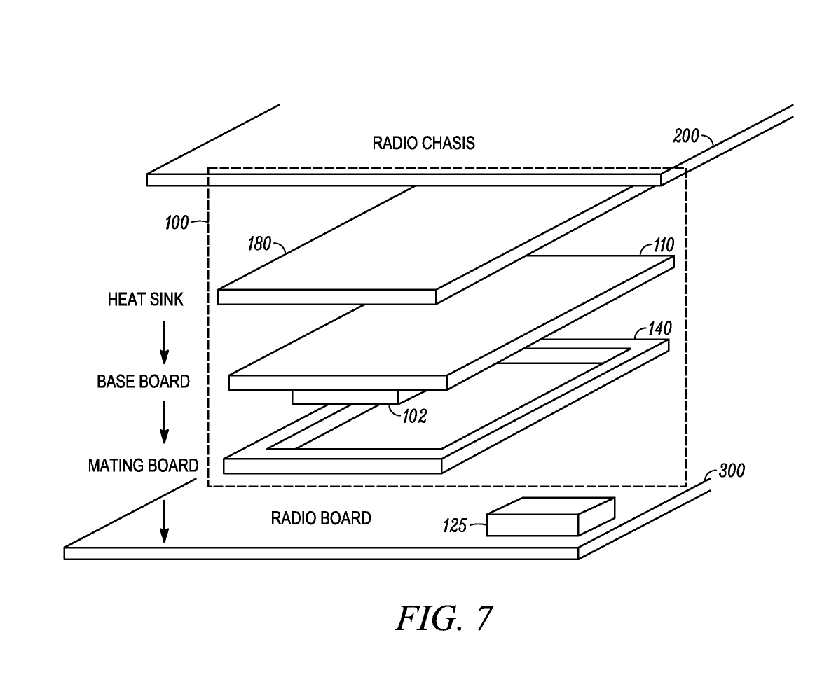

Referring to FIG. 7, a perspective view of the scalable device 100 coupled to a radio board 300 is shown. It should be noted that the perspective view is presented upside down with respect to FIG. 5 to illustrate the mating of the scalable device 100 to the radio board 300. In particular, the perspective view illustrates how the mating board 140, the circuit board 110, and the heat sink 180 are assembled together with the radio chassis 200 and the radio board 300. Notably, the heatsink 180 can be placed in direct contact with the radio chassis 200 to dissipate heat. Briefly, the scalable device 100 contains the active devices 102 which are power amplifier die for providing multi-band operation. In the arrangement shown, the scalable device 100 is specific to radio communication and more specifically transmitting communication signals in different frequency bands. The scalable device 100 is connected to the radio board 300 to provide complete radio operation. For example, the radio board 300 may contain processors 125 or other electronic components for modulating communication signals prior to amplification by the scalable devices 102.

The scalable device 100, while being extremely small, can dissipate over 10 Watts of power. Since the scalable device 100 can be used for several different transmit bands, it can accommodate a variety of active device 102 sizes. However, the maximum power that can be dissipated through the radio board 200 is approximately 1 Watt. Accordingly, the scalable device 100 removes heat from a top portion via direct contact with the radio chassis 200 instead of dissipating heat through the radio board 300. That is, the heatsink 180 is placed away from the radio board 300 and in direct contact with the radio chassis 200 to dissipate heat. Notably, the active devices 102 can be perceived in such context as being upside down in the scalable device 100. In particular, the active devices 102 are soldered through the circuit board 110 to the heat sink 180. That is, the portions of the active devices 102 generating the most heat are mechanically coupled to the heatsink 180. The package of the scalable device 100 is small to maximize scarcity of board space in a multiband environment.

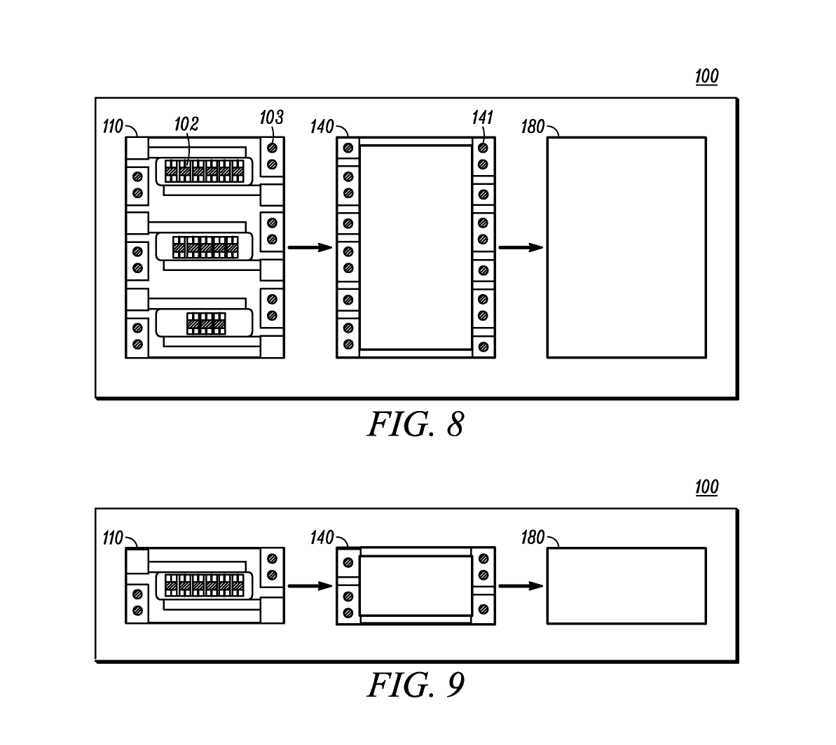

Referring to FIG. 8, a diagram of the components of the scalabe device 100 is shown. It should be noted that the leads 103 of the circuit board 1 10 extend to pads 141 of the mating board 140 at pre-configured locations for providing interchangeability in accommodating active devices of differing sizes. That is, the circuit board 100 is physically configured by design to accept different power amplifier dies having different sizes or pin layouts. The pins of the power amplifier dies can be brought to the pre-configured locations along the perimeter of the circuit board 110. For example, the leads 103 of the active device can be passed to the pad 141 on the mating board 140 for extending the electrical connection of the leads 103. This ensures scalability and interchangeability for power amplifier dies having differing sizes and pin layouts.

In practice, the pads 141 of the mating board 140 can be electrically connected to the radio board 300 (see FIG. 7). The radio board has pads that align with the pre-configured locations such that active devices can be interchanged without re-routing the leads. In such regard, the traces and pads on the radio board 300 will accept either individual packages or multiple die packages equally. Referring back to FIG. 8, the scalable device 100 packages themselves are designed assemblies which have a minimal footprint. That is, the scalable device 100 is preconfigured to accept various power amplifier die from different manufacturers. This enables a manufacturer of the scalable devices 100 to place any combination of die on the board depending on customer orders or manufacturing strategy while consuming the least amount of board space possible. For example, as shown in FIG. 8, three active devices (e.g. power amplifier die) are shown. Whereas, in FIG. 9, only one active device (e.g. power amplifier die) is shown Recall, the scalable device 100 package consists of three parts: a heatsink 180 possibly made of a single substrate such as copper or other similar metal, a printed circuit board 110, and a mating board 140, also made out of printed circuit board. These parts, when assembled, create a cavity which protects the wire bonds. Referring back to FIG. 7, the cavity is the opening of the mating board 140. The scalable device 100 is mounted to the radio board 300 (see FIG. 7) with the heat sink up, and making contact with the radio chassis 200 (See FIG. 6) to dissipate excess heat.

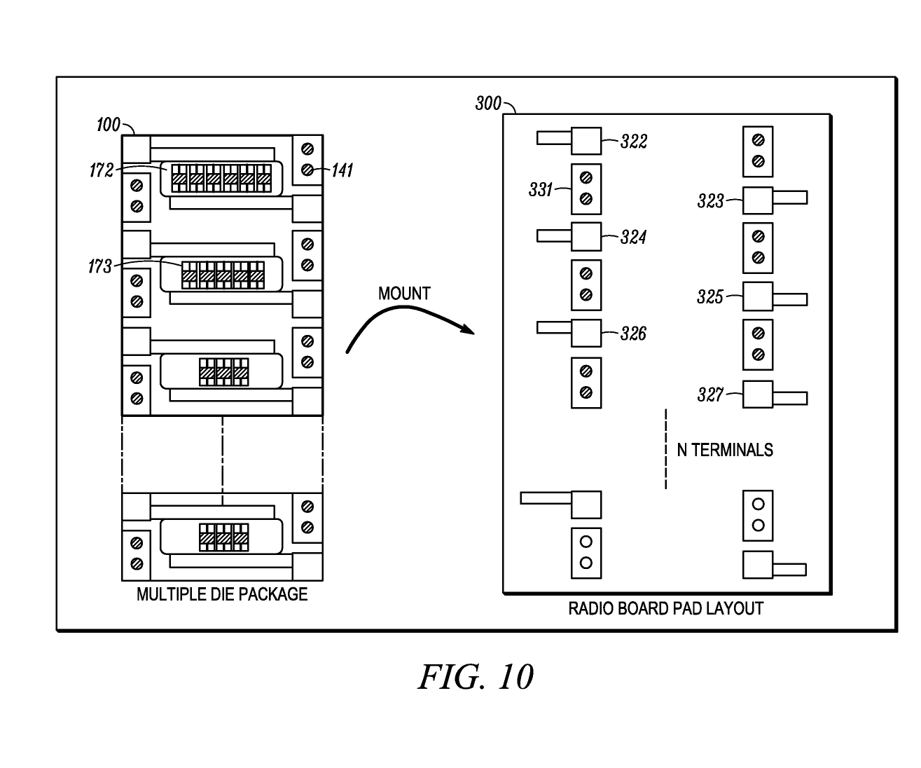

Referring to FIG. 10, an illustration for mounting the scalable device 100 to the radio board 300 is shown. As an example, the scalable device 100 can include multiple die packages 172 and 173. Notably, the scalable device 100 is electrically soldered to the radio board 300 at specific locations. The radio board 300 includes a layout of traces for connecting leads of the active devices on the circuit board to the radio board 300. The traces are solder connection points, such as 322-327, for providing electrical connection to the pins of the active devices 172 and 173. Recall, the mating board 140 (see FIG. 7) passes leads 103 of the circuit board 110 to pads 141 on the scalable device 100. Directly referring to FIG. 10, the pads 141 are soldered to corresponding traces (322-327) on the radio board 300.

Notably, the layout of the traces is the same regardless of the active device used. That is, the scalable device 100 can accept different power amplifier dies without changing a configuration of the layout on the radio board. In such regard, the pads 141 are at pre-configured locations to provide scalability and interchangeability of different active devices 102. For instance, it can be seen that active device 172 contains six power amplifier cells, whereas active device 173, contains only 4 cells. The gate pad 322 and the drain pad 323 for active device 172 also align with the gate pad 324 and the drain pad 325 for active device 173, which allows interchangeability. That is, active device 172 can be switched out for active device 173, or any other active device. In such regard, the pads of the layout in the radio board 300 are compatible with all possible package combinations. A manufacturer can populate the board with the proper die for each band, combining multiple die packages with single die packages easily. A manufacturer can elect to include any number of active devices as deemed necessary. In one arrangement, it may be desirable to include all the silicon necessary to cover all bands and to turn different bands on in the future using software.

Building radios capable of covering all the major RF bands simultaneously gives rise to new manufacturing strategies. For instance, a three band radio can be built and fully populated with each radio being programmed to operate in customer specified bands. Customers can return to the manufacturer to have additional bands activated for a fee. In this case, the power amplifier final stages can be packaged individually or they can be contained within one package. Another strategy is for the manufacturer to populate only those bands ordered by the customer, thus saving the parts cost for the undesired bands.

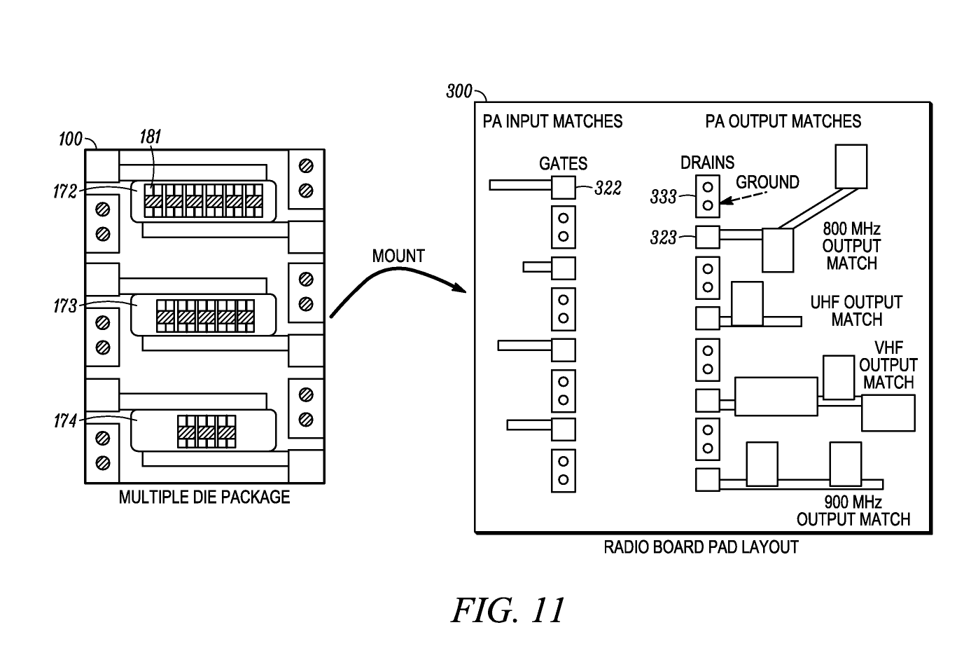

Referring to FIG. 11, an exemplary three band radio for mounting a multiple die package of the scalable device 100 is shown. For example, the scalable device 100 can include a first active device 172 for providing 800 MHz band amplification, a second active device 173, for providing UHF band amplification, and a third active device 174, for providing VHF band amplification. Each active device is a single die comprised of one or more cells. For example, active device 172 can contain 6 cell die. Each die may be a FET amplifier having a gate and drain connection. Each of the gates of the FET can be tied to a common connection 322 on the radio board 300. Similarly, each of the drains can be tied to a common connection 323 on the radio board.

The die is arranged in the device package 100 to be aligned with the signal flow from gate to drain, thus minimizing the size of the scalable device 100 and the amount of

material used. Power amplifier die used in portable radios are typically shaped like long rectangles. The long sides of the rectangle are much longer than the short sides. Older designs positioned the long sides of the die orthogonally to the signal flow and included several ground connections which have been found to be unnecessary. This configuration of the gate 322 and drain 323 connections of the scalable device 100 shown in FIG. 10 share the same footprint and can be used interchangeably with multiple die packages.

Notably, the gate 322 and drain 323 for each active device can be arranged along a longest dimension of the active device to minimize overall package size. For example, the longest dimension of the package die may be the length, which is oriented with a signal flow from gate 322 to drain 323. Moreover, the traces of the radio board layout reduce superfluous ground connections 333 so as to further minimize overall package size.

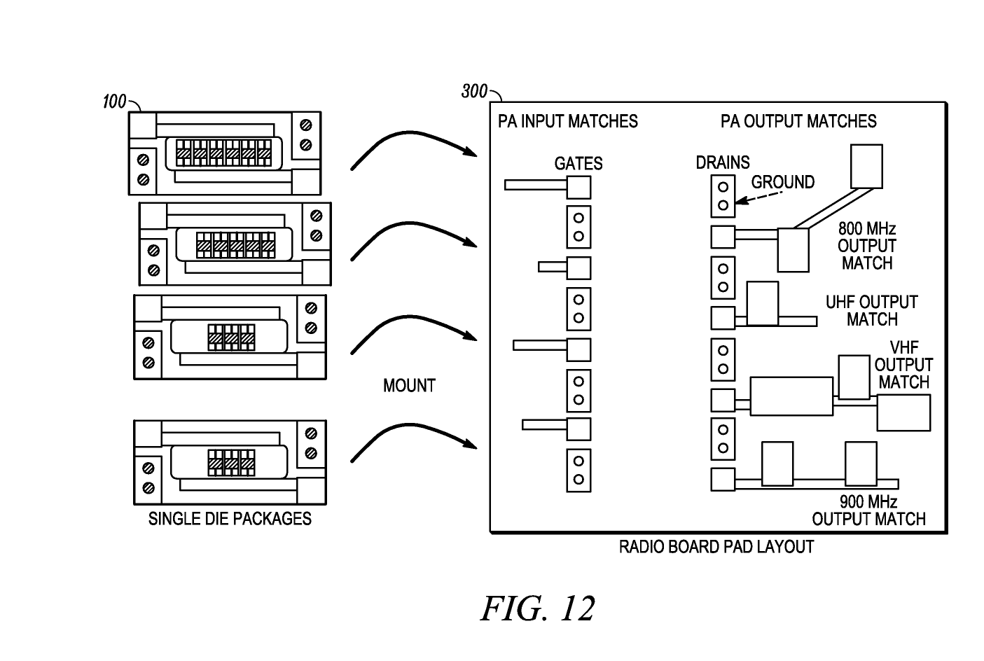

Referring to FIG. 12, an exemplary multiband band radio for mounting single die packages of the scalable device 100 is shown. In particular, each scalable device 100 includes a circuit board containing an active device, a mating board, and a heat sink as previously shown in FIG. 5. For example, the first scalable device 172 provides 800MHz band amplification, the second scalable device 173 provides UHF band amplification, and the third scalable device 174 provides VHF band amplification. Notably, the trace layout of the radio board providing the electrical solder connection points for the scalable devices 100 are similarly arranged. For example, the gate 322 for the first, second, and third device is in an upper left location, whereas the drains 323 for the first, second, and third device are at lower right locations. This allows, for the interchangeability of different scalable devices 100.

Where applicable, the present embodiments of the invention can be realized in hardware, software or a combination of hardware and software. Any kind of computer system or other apparatus adapted for carrying out the methods described herein are suitable. A typical combination of hardware and software can be a mobile communications device with a computer program that, when being loaded and executed, can control the mobile communications device such that it carries out the methods described herein. Portions of the present method and system may also be embedded in a computer program product, which comprises all the features enabling the implementation of the methods described herein and which when loaded in a computer system, is able to carry out these methods.

While the preferred embodiments of the invention have been illustrated and described, it will be clear that the embodiments of the invention is not so limited. Numerous modifications, changes, variations, substitutions and equivalents will occur to those skilled in the art without departing from the spirit and scope of the present embodiments of the invention as defined by the appended claims.

What is claimed is:

1. A miniature die mounting apparatus suitable for use in a radio, comprising:
a heatsink;
a circuit board containing a plurality of active devices having leads to a perimeter of the circuit board, wherein the plurality of active devices are in coplanar contact with the heatsink; and
a mating board having an opening, wherein the mating board attaches along the perimeter of the circuit board to pass the leads of the circuit board for extending a connection of the active devices, wherein the opening protects wire bonds of the plurality of active devices.

2. The miniature die mounting apparatus of claim 1, wherein the leads of the circuit board extend to pads of the mating board at pre-configured locations for providing interchangeability in accommodating active devices of differing sizes.

3. The miniature die mounting apparatus of claim 2, wherein the mating board is mounted to a radio board of the radio, and the radio board has pads at compatible locations with the pre-configured locations that accept either individual Integrated Circuit (IC) packages or multiple IC packages equally.

4. The miniature die mounting apparatus of claim 1, wherein the heatsink provides a planar surface for efficiently dissipating heat from the plurality of active devices when the heatsink is in direct contact with at least a portion of a chassis of the radio.

5. The miniature die mounting apparatus of claim 1, wherein the active devices are arranged on the circuit board and aligned with a signal flow from gate to drain to minimize a size.

6. The miniature die mounting apparatus of claim 5, wherein a longest dimension of an active device is arranged parallel to the signal flow.

7. The miniature die mounting apparatus of claim 1, wherein the miniature die mounting apparatus is a leadless, surface mount package design.

8. The miniature die mounting apparatus of claim 1, wherein an active device is a die for a power amplifier.

9. A miniature multiple die packaging assembly suitable for use in a radio, comprising:
a heatsink having contact with a chassis of the radio;
a circuit board containing a plurality of active devices having leads to a perimeter of the circuit board, wherein the plurality of active devices are in contact and coplanar with the heatsink; and
a mating board having an opening, wherein the mating board attaches along a top perimeter of the circuit board to pass the leads of the circuit board for extending a connection of the active devices to a radio board.

10. The miniature multiple die packaging assembly of claim 9, wherein the mating board brings the leads of the plurality of active devices to pre-configured locations along the perimeter.

11. The miniature multiple die packaging assembly of claim 10, wherein the radio board has pads that align with the pre-configured locations such that active devices can be interchanged.

12. The miniature multiple die packaging assembly of claim 10, wherein the circuit board accepts single package die or multiple package dies of the plurality of active devices.

13. The miniature multiple die packaging assembly of claim 12, wherein a longest dimension of the package die is oriented with a signal flow from gate to drain.

14. A scalable interchangeable multiband power package mounting device suitable for use with a radio, comprising:
a heatsink having contact with a chassis of the radio;
a circuit board containing a plurality of power amplifier dies having leads to a perimeter of the circuit board, wherein the plurality of power amplifier dies are in contact with the heatsink; and
a mating board peripheral to the circuit board and extending above the circuit board to pass the leads of the circuit board for extending a connection of the power amplifier dies.

15. The scalable interchangeable multiband power package mounting device of claim 14, wherein the leads are arranged on the mating board at pre-configured locations for providing interchangeability of power amplifier dies of different sizes.

16. The scalable interchangeable multiband power package mounting device of claim 14, wherein the plurality of power amplifier dies are coplanar with the heatsink.

17. The scalable interchangeable multiband power package mounting device of claim 16, wherein the heatsink is in direct contact with a chassis of the radio.

18. The scalable interchangeable multiband power package mounting device of claim 17, wherein the mating board is connected to a radio board of the radio at pads corresponding to the preconfigured locations.

19. The scalable interchangeable multiband power package mounting device of claim 18, wherein heat is dissipated via the heatsink to the chassis.

20. The scalable interchangeable multiband power package mounting device of claim 18, wherein the heatsink is a single substrate.
